(19) United States
(12) Patent Application Publication
(10) Pub. No.: US 2008/0198538 A1
(43) Pub. Date: Aug. 21, 2008

(54) Battery modules and housing structures thereof

(75) Inventor: Han Pin Chien, Taoyuan County (TW)

Correspondence Address: Joe McKinney Muncy, PO Box 1364, Fairfax, VA, 22038-1364, US

(73) Assignee: Dynapack International Technology Corp.

(21) Appl. No.: 11/708,358

(22) Filed: Feb. 21, 2007

(51) Int. Cl. H05K 7/00

(52) U.S. Cl. 361/679

(57) ABSTRACT

Battery modules are provided. A battery module for a portable electronic device includes a first case, a second case, a battery cell enclosed by the first and second cases, a spacing means, and an adhesive. The first case includes a first surface, and the second case includes a second surface corresponding to the first surface. The spacing means is disposed between the first and second surfaces, forming a gap therebetween. The adhesive is disposed in the gap to connect the first and second surfaces of the first and second cases.

### BACKGROUND OF THE INVENTION

1. Field of the Invention

The invention relates in general to battery modules and more particularly to battery modules for portable electronic devices.

2. Description of the Related Art

Referring to FIG. 1, a conventional battery module primarily comprises battery cell 30 enclosed by a first case 10, a second case 20. During assembly, two fasteners S are inserted through the first and second cases 10 and 20, such that the first and second cases 10 and 20 are firmly connected. The first and second cases 10 and 20 may also be electrically connected by the fasteners S, to provide an ESD shield for the battery module. The fasteners S, however, may thrust into the battery cell 30 during assembly and cause damage.

### BRIEF SUMMARY OF THE INVENTION

Battery modules are provided. A battery module for a portable electronic device includes a first case, a second case, a battery cell enclosed by the first and second cases, a spacing means, and an adhesive. The first case includes a first surface, and the second case includes a second surface corresponding to the first surface. The spacing means is disposed between the first and second surfaces, forming a gap therebetween. The adhesive is disposed in the gap to connect the first and second surfaces of the first and second cases.

### BRIEF DESCRIPTION OF THE DRAWINGS

The invention can be more fully understood by reading the subsequent detailed description and examples with references made to the accompanying drawings, wherein:

FIG. 1 is a sectional view of a conventional battery module;

FIG. 2 is an exploded diagram of a battery module;

FIG. 3 is a sectional view of a gap formed between a first case and a second case;

FIG. 4 is a sectional view of a spacing means having a contact surface abutting a first surface of a first case; and

FIG. 5 is a perspective diagram of a flexible conductor electrically connecting a first case and a second case.

### DETAILED DESCRIPTION OF THE INVENTION

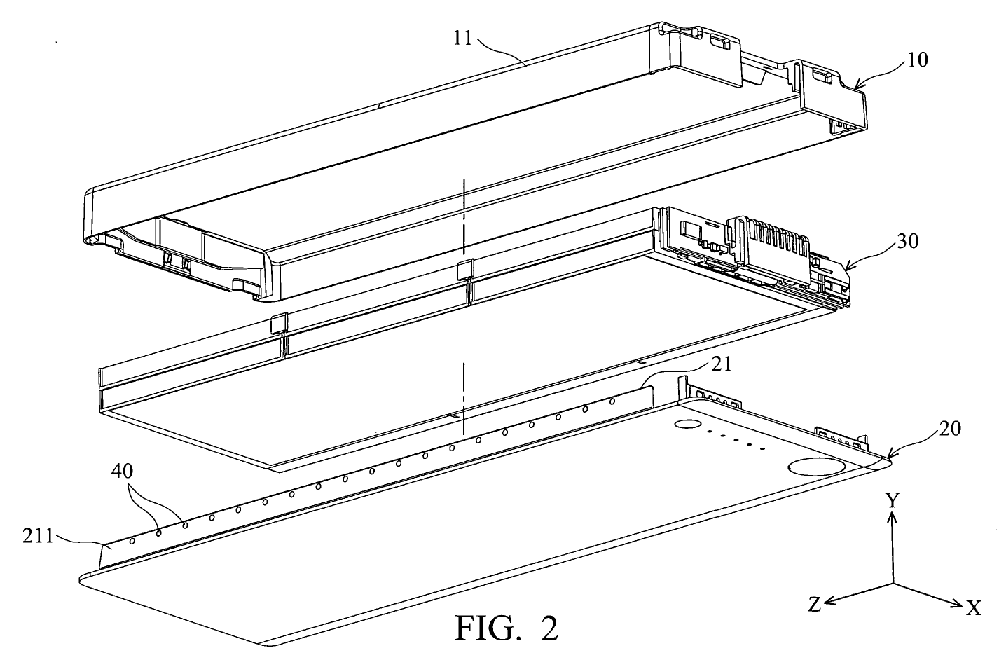

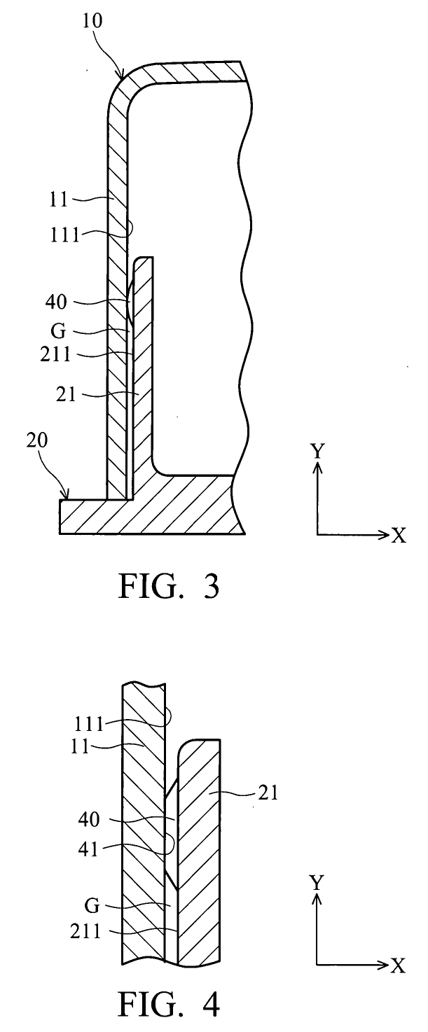

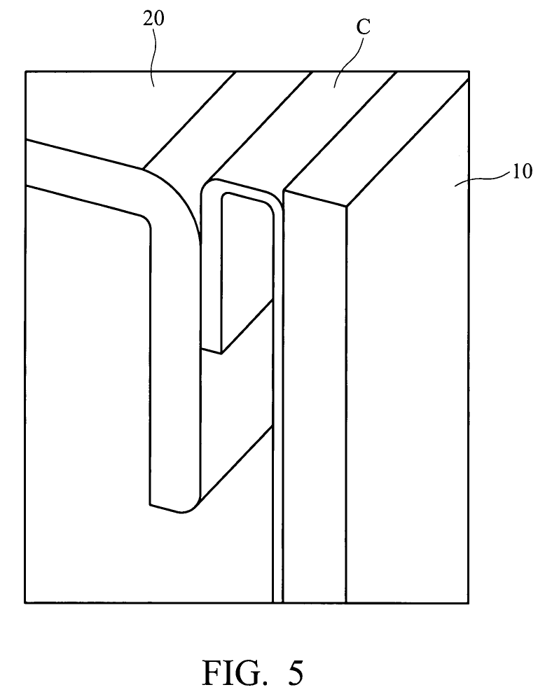

Referring to FIG. 2, an embodiment of a battery module for a portable electronic device primarily comprises a first case 10, a second case 20, and a battery cell 30 enclosed by the first and second cases 10 and 20. The first case 10 comprises a side wall 11 having a first surface 111, and the second case 20 comprises a side wall 21 having a second surface 211 corresponding to the first surface 111, as shown in FIGS. 2 and 3. In this embodiment, the second case 20 further comprises a plurality of spacing means 40 projecting from the second surface 211.

Referring to FIG. 3, during assembly, a gap G is formed between the first and second surfaces 111 and 211 by the spacing means 40 abutting the side wall 11 of the first case 10. Hence, the first and second cases 10 and 20 can be firmly connected by applying adhesive within the gap G. The spacing means 40, such as nubs formed monolithically with the second case 20, has a spherical surface substantially in point contact with the first surface 111. The spacing means 40 may also be formed monolithically with the first case 10, projecting from the first surface 111 and contacting the second surface 211. In some embodiments, the spacing means 40 can also be individual elements disposed between the first and second surfaces 111 and 211, to form the gap G therebetween.

As shown in FIG. 4, another embodiment of a spacing means 40 projects from the second surface 211 and has a contact surface 41 abutting the first surface 111. The contact surface 41 can be round, polygonal or other symmetrical shape, facilitating robust connection between the first and second cases 10 and 20.

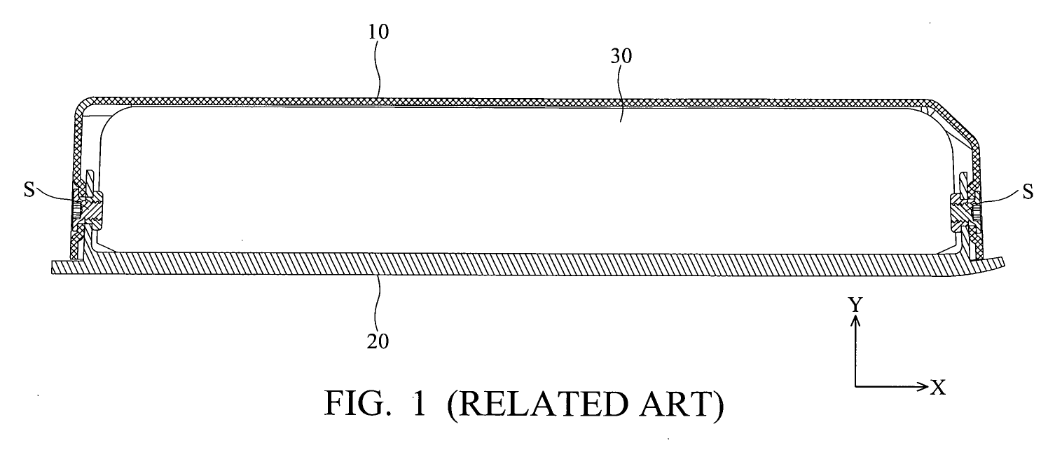

To prevent electrostatic discharge (ESD), the battery module further comprises a flexible conductor C physically contacting the first and second cases 10 and 20, rather than the fasteners S shown in FIG. 1. In some embodiments, the flexible conductor C can be a metal spring sheet electrically connecting the first and second cases 10 and 20, enhancing ESD shielding of the battery module.

Battery modules and housing structure thereof are provided according to the embodiments. A gap G is formed between the first and second cases 10 and 20 of the housing structure by the spacing means 40, as shown in FIG. 3. Thus, an adhesive can be evenly applied in the gap G to firmly connect the first and second cases 10 and 20. Rather than conventional fasteners S shown in FIG. 1, the present invention enables simpler assembly and prevents damage to battery cell 30.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A battery module for a portable electronic device, comprising:
a first case, comprising a first surface;
a second case, comprising a second surface;
a spacing means, disposed between the first and second surfaces to form a gap therebetween;
an adhesive, disposed in the gap to connect the first and second surfaces of the first and second cases; and
a battery cell, enclosed by the first and second cases.

2. The battery module as claimed in claim 1, wherein the spacing means is monolithically formed with the second case and projects from the second surface.

3. The battery module as claimed in claim 1, further comprising a plurality of spacing means between the first and second surfaces.

4. The battery module as claimed in claim 1, wherein the spacing means is substantially in point contact with the first surface.

5. The battery module as claimed in claim 1, wherein the spacing means has a round contact surface in contact with the first surface.

6. The battery module as claimed in claim 1, wherein the spacing means has a polygonal contact surface in contact with the first surface.

7. The battery module as claimed in claim 1, wherein the spacing means has a symmetrical contact surface in contact with the first surface.

8. The battery module as claimed in claim 1, further comprising a flexible conductor electrically connects the first and second cases.

9. The battery module as claimed in claim 8, wherein the flexible conductor comprises a spring sheet contacting the first and second cases.

10. The battery module as claimed in claim 9, wherein the flexible conductor comprises metal.

11. A housing structure of a battery module, comprising:
a first case, comprising a first surface;
a second case, comprising a second surface;
a spacing means, disposed between the first and second surfaces to form a gap therebetween; and
an adhesive, disposed in the gap to connect the first and second surfaces of the first and second cases.

12. The housing structure as claimed in claim 11, wherein the spacing means is monolithically formed with the second case and projects from the second surface.

13. The housing structure as claimed in claim 11, further comprising a plurality of spacing means between the first and second surfaces.

14. The housing structure as claimed in claim 11, wherein the spacing means is substantially in point contact with the first surface.

15. The housing structure as claimed in claim 11, wherein the spacing means has a round contact surface in contact with the first surface.

16. The housing structure as claimed in claim 11, wherein the spacing means has a polygonal contact surface in contact with the first surface.

17. The housing structure as claimed in claim 11, wherein the spacing means has a symmetrical contact surface in contact with the first surface.

18. The housing structure as claimed in claim 11, further comprising a flexible conductor electrically connects the first and second cases.

19. The housing structure as claimed in claim 18, wherein the flexible conductor comprises a spring sheet contacting the first and second cases.

20. The housing structure as claimed in claim 19, wherein the flexible conductor comprises metal.
